(19) United States
(12) Patent Application Publication
(10) Pub. No.: US 2011/0023541 A1
(43) Pub. Date: Feb. 3, 2011

(54) Process For Manufacturing Cross-Corrugated Packings

(75) Inventors: Jean-Christophe Rostaing, Versailles (FR); Fabrice Del Corso, Saclay (FR); Francois Leclercq, Lyon (FR); Julien Alfonsi, Paris (FR)

Correspondence Address: American Air Liquide, Inc.;Intellectual Property Dept., 2700 Post Oak Boulevard, Suite 1800, Houston, TX, 77056, US

(73) Assignee: L'Air Liquide Societe Anonyme Pour L'Etude Et L'Exploitation Des Procedes Georges Claude, Paris (FR)

(21) Appl. No.: 12/934,450

(22) PCT Filed: Mar. 5, 2009
(86) PCT No.: PCT/FR09/50353

§ 371 Date: Sep. 24, 2010

(30) Foreign Application Priority Data
Mar. 28, 2008 (FR) 0852031

(51) Int. Cl. F25J 3/00; C23C 16/50; B05D 1/02; B05D 1/18; B24B 1/00; C23C 16/511

(52) U.S. Cl. 62/643; 427/569; 427/421.1; 427/430.1; 451/28; 427/575

(57) ABSTRACT

A process for manufacturing cross-corrugated packings is provided.

The present invention relates to a process for manufacturing cross-corrugated packings.

The packings ordinarily used are formed by corrugated strips comprising alternating parallel corrugations each lying in a vertical general plane and against one another. The corrugations are oblique and descend in opposite directions from one strip to the next one. The degree of perforation is about 10% for these cross-corrugated packings.

GB-A-1 004 046 discloses packings of the cross-corrugated type.

CA-A-1 095 827 provides an improvement to this type of packing by adding a dense perforation of small-diameter apertures so as to allow the liquid to flow on either side of the cross-corrugated strips.

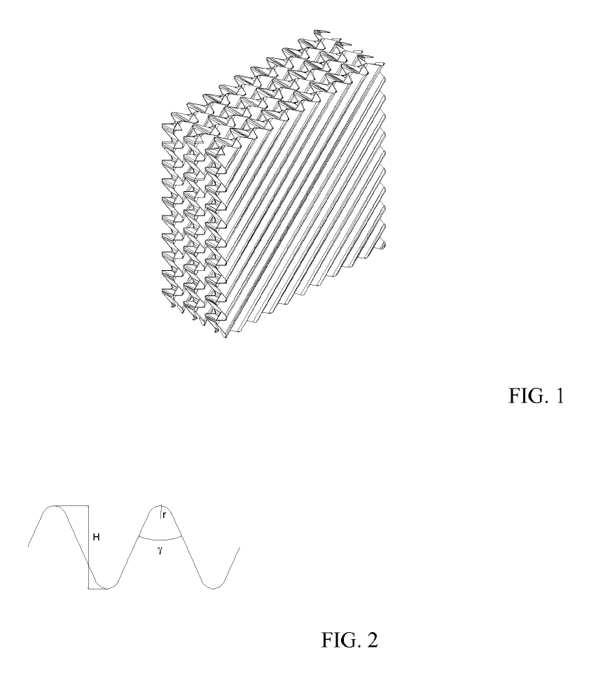

This packing, as illustrated in FIG. 1, is generally manufactured from a flat product: metal sheets in the form of strips. The strips are firstly folded (or bent) so as to form a kind of corrugated sheet in strip form, the corrugations of which are oblique with respect to the axis of the strip. The folded strips are then cut into sections and then stacked, every other strip being alternately inverted.

The packing sections thus obtained are called modules.

In the case of simple corrugations, as shown in FIG. 2, the various parameters for describing a cross-corrugated packing are: the height of the corrugations (H), the folding angle (ρ), the radius of curvature (r) and the inclination of the corrugations (δ).

The object of the invention is to improve the technology of structured packings.

The structured characteristic of the packing intrinsically ensures that there is good response to functions in what is called the “spanning” zone.

The importance of the interface zone between modules has been demonstrated in the developments of packings with a modified interface (MELLAPACK+de SULZER CHEMTECH packings).

A slight modification of the interface between modules has delayed the onset of flooding, and therefore has achieved significant increases in capacity of distillation columns (to be connected with the function of “ensuring flow of the liquid counter-currently to the gas”) with virtually no degradation in the mass exchange performance (to be connected with the function of “maintaining the gas/liquid contact surface”).

In the literature, the announced purpose of this slight interface modification is to reduce the gas pressure drop at the interface.

In conventional cross-corrugated packings, the gas is constrained to change direction through an angle of approximately 90° when passing from one module to another, hence a particularly large pressure drop in this “interface” zone. In a modified “interface” packing of the MELLAPACK+type, this particular pressure drop is provided by the spanning zone: the gas does not change direction at the “interface”, but before and after it.

In the literature, this phenomenon is often analyzed in terms of liquid retention in the bottom portion of the modules near the “interface”: the pressure drop suffered by the gas on changing direction causes liquid to accumulate in neighboring zones. The accumulation of liquid causes premature flooding of the column.

To increase the capacity of columns, other means for limiting the gas pressure drop at the interface between the modules have been devised:
U.S. Pat. No. 5,013,492 discloses vertically offsetting every other packing strip in the modules so as to reduce the density near the interfaces;
FR-A-2 686 271 discloses spacers inserted between the modules;
JP-A-6 312 101 discloses lower-density modules inserted between the distillation modules;
U.S. Pat. No. 5,632,934 discloses reducing the corrugation height, changing the inclination of the channels and producing openings near the base of the modules; and
WO-A-97/16247 discloses progressively changing the inclination of the channels up to the vertical at the edges of the strips and installing gratings between the modules.

Another possible interpretation of these phenomena is that, at the “interface” between modules, between the moment when the liquid film leaves the upper module and when it reaches the lower module, said film no longer benefits from the retention by capillary effect of the surface of the packing in order to resist the thrust of the ascending gas.

The liquid film may therefore be more easily disturbed and, as it is no longer retained, it breaks up into large droplets, causing local flooding. The function of “ensuring flow of the liquid counter currently to the gas” is therefore less easily fulfilled in the “interface” zone between modules.

Other trials comparing a conventional packing with an “interface” packing modified by the addition of spacers between modules have shown the importance of guiding the liquid. Specifically, by adding spacers the path of the liquid in free fall between two modules is extended (and therefore there is a longer time during which the liquid can be more easily disturbed). This may explain the observed degradation in capacity during trials.

One object of the invention is to provide a process for treating a mass and/or heat transfer module, the device comprising a stack of cross-corrugated plates, in which the wetting of the surface of the plates is reduced in at least one zone of the module, characterized in that the wetting is reduced only in at least one of the bottom and top interface zones of the module.

According to other optional aspects:
the wetting is reduced by polishing the surface of the plates in at least one interface zone of the module;
the wetting is reduced by chemically treating the surfaces of the plates in at least one interface zone of the module;
the zone is immersed in a chemical bath or sprayed with a solution;
the wetting is reduced by providing a physical and/or chemical treatment using a reactive gaseous atmosphere excited by an electrical discharge, in particular an atmospheric-pressure electrical discharge;
the electrical discharge being of the corona discharge, dielectric barrier discharge (DBD) or microwave discharge type;
the wetting of at least one interface zone of the plate is reduced before or after folding;
the wetting of the surface of the plates of the module is increased in the central zone of the module;
the wetting is increased by immersing the plate in a liquid bath or by spraying it with a solution;
the wetting is increased by providing a physical and/or chemical treatment using a reactive gaseous atmosphere excited by an electrical discharge, in particular an atmospheric-pressure electrical discharge;
the electrical discharge being of the corona discharge, dielectric barrier discharge (DBD) or microwave discharge type;
the wetting of at least one zone of the module is reduced, with a gradient of properties of the plasma atmosphere through the module;
the concentration of the injected gases and/or the electron density and electron temperature of the plasma is/are varied along the module;
the changes in wetting properties are progressive between two contiguous zones;
the wetting modification is combined with at least one modification in the geometry, density or material of the zone;
the plates are made of aluminum;
the plates are made of copper.

According to the invention, a packing module treated as described above is provided.

For a module having a central zone and two outer zones, at least one outer zone is treated according to one of the processes described above.

According to the invention, a column equipped with at least one packing module described above, in particular an air gas distillation column, is provided.

The invention consists in adapting the wettability of the surface of the packing by the cryogenic liquid, functionalized in the various zones of the module. To do this, a surface treatment is carried out on the packing sheets during their manufacture, this treatment being applied in line before or after stamping.

Thus, in the spanning zone or in the interface zone at the top of the module, the aim will be firstly to retain more liquid so as to provide:
a longer time in contact with the gas;
better “wetting”, and therefore a higher gas/liquid contact area,
   and therefore to improve mass transfer.

In the interface zone at the bottom of the module, the aim will be to drain the liquid as much as possible, so as to prevent it from accumulating at the edges of the module and to promote flow as liquid streams in order to limit liquid detachment.

Such optimization options are also available in the distillation column:
>the physical properties of the fluids may vary depending on the temperature in the column. Thus, they may be more viscous or less viscous (having a different viscosity) or more wetting or less wetting (having a different surface tension).

To counterbalance this variation in the physical properties, the surface may thus be functionalized so as to make it:
more wetting at the point where the liquid is more viscous or less wetting;
less wetting at the point where the liquid is less viscous or more wetting;
>the liquid flow rates per unit area of the packing may vary depending on the position in the column. Certain zones may have a higher liquid loading or a lower liquid loading than others. To counterbalance these variations in liquid loading, the surface may thus be functionalized so as to make it:
more wetting at the point where the liquid loading is low;
less wetting at the point where the liquid loading is high.
>The packing modules are organized by sections in the column. A section is located between a bottom gas inlet and, in general, a top liquid manifold.

At the top of a section, the surface may thus be functionalized for rapid wetting of the packing surface by the liquid falling from the manifold.

At the bottom of a section, the surface may be functionalized in order to reduce the wetting, so as to reduce the interaction with the incoming gas and to limit liquid wicking.

To adapt, as required, the wettability of the aluminum surface initially covered with its native alumina layer, the physico-chemical modifications of this surface may consist in particular in:
1. etching and pickling;
2. changing the roughness;
3. creating a microtexture;
4. grafting of chemical functions;
5. deposition of thin films of filler materials, etc.

For modifications of type 1, 2 and 3, mechanical treatments of packings have already been described in the prior art, especially in the patents U.S. Pat. No. 4,604,247, U.S. Pat. No. 4,296,050 and EP-A-0 190 435. This prior art clearly describes the application of these treatments to the entire surface of the packing and not to specific zones to be functionalized, as described in the present patent application.

Other means are also possible for achieving the desired modifications.

Preferably, the surface treatment is applied using a gaseous phase and most particularly a cold plasma, especially because the permissible temperature for treating a thin aluminum sheet is very limited. Finally, an atmospheric-pressure plasma process appears best suited for a high-yield continuous treatment with the requirement of a low cost. The corresponding device can be easily integrated into the plant used for the continuous manufacture of packings.

Depositing thin films of material is the most advantageous way of modifying the wettability of the aluminum surface. This is because a microtexturing process generally requires halogenated gases, which pose safety and environmental problems and therefore involve additional constraints and costs. Moreover, a microtextured surface may have a reactivity which is much less understood and in any case less reproducible vis-à-vis oxygen under accidental combustion initiation conditions.

Simple grafting of a chemical function may prove to be insufficient. This is because the packing must maintain the very specific level of wettability, which will have been imparted to it during manufacture, for many years of service, whereas permanent contact with liquid or two-phase oxygen will certainly have an effect on the grafted functionalities (which it will be recalled involve a minute amount of material on the surface), modifying the wetting properties over the course of time.

However, a wide range of materials that can be deposited as a thin film using a chemically reactive plasma is known, the wettability of these materials ranging from highly hydrophobic to highly hydrophilic. This behavior was, at least hitherto, with respect to water, and it will therefore be necessary to “recalibrate” the wettabilities of these materials by the cryogenic liquids in question, under the conditions prevailing in a given zone of a module or a column.

The principle of PECVD (plasma-enhanced chemical vapor deposition) consists in exciting, in an electrical discharge plasma close to or in contact with the substrate, a chemical vapor of precursors of the various elements to be incorporated into the material as a thin film. For example, to deposit silica, a mixture of monosilane SiH₄ and oxygen is used. In the plasma, the initial chemical molecules are dissociated into smaller fragments, especially radicals with a very high chemical energy with respect to a surface, which radicals will condense on said surface and then be incorporated into the film of material in the process of growing, irreversibly forming strong bonds. The advantage of the PECVD process is that, owing to the very high radical reactivity conferred by the electrical excitation, the thin film of material may form on the surface of a substrate without it being necessary to heat the surface appreciably, and even at almost ambient temperature.

As an example of materials having controlled properties, thin silicon nitride films are generally hydrophobic, as are fluorocarbon polymer films. It is also possible to obtain hydrophobic films of materials prepared from gaseous organosilicon precursors.

In contrast, silica SiOₓ and titanium oxide TiO₂ films for example are hydrophilic.

All these materials are amorphous and it is possible to achieve any “intermediate” alloy composition by combining several gaseous precursors of the various elements to be incorporated in a PECVD process. Thus, by continuously varying the composition between the hydrophilic material and the hydrophobic material, it is possible in principle to achieve any wettability value. It is particularly simple to adjust the composition in a PECVD process since all that is required is to change the ratios of the flow rates of the various gaseous chemical precursors. It is also possible to vary the composition of the material, and therefore the wettability thereof, spatially along the direction perpendicular to the direction in which the packing strip runs during a continuous treatment thereof (i.e. varying it over the height of the module). To do this, it is sufficient to inject a gas mixture having a composition that varies suitably along said direction, this posing no big problem when operating at atmospheric pressure.

To carry out an atmospheric PECVD process requires a suitable device for exciting the plasma. There are two families of nonthermal atmospheric “plasma sources” (i.e. as opposed to, for example, welding arcs). The first family is that of dielectric barrier discharges, which may exist in filamentary or homogeneous (glow) mode. Only this mode is suitable for implementing a PECVD process, but its operating conditions are restricting and in particular direct treatment of conducting substrates is not possible. This means that it is not possible for the packing strip to run between two electrodes.

The second family is that of atmospheric microwave discharges which have the advantage of a high electron density, and therefore a high yield in converting the gaseous precursors and paying a high deposition rate, which is a very important aspect in applications in which a high cost constraint exists. It is particularly advantageous to use a flowing linear plasma source, i.e. one generating a plasma “curtain” incident on the surface of the packing strip and extending perpendicular to the run direction. Such a plasma source is described in French patent application FR 07/57719 of Sep. 20, 2007, and the way it is applied for producing a device and for carrying out a PECVD process is described in French patent application FR 07/57720 of Sep. 20, 2007, both patent applications in the name of the Applicant. The dilution gas may be nitrogen, argon or a mixture of the two. A sealed chamber serves for confining the active gases in the deposition zone, so as to prevent polluting emissions into the atmosphere of the manufacturing building. The system is also provided with a means of decontaminating the spent gases before discharging them into the atmosphere. Automatic control mechanisms are used to ensure traceability of the wetting characteristics of each manufactured batch, according to its use in the module or in the column.

The thin film deposition may be carried out on the smooth aluminum sheet before stamping, this posing the problem of maintaining its integrity during the latter operation, but it may also be carried out downstream of the stamping. In this case, it may be necessary, before the actual deposition, to clean the surface so as to ensure good adhesion of the film that will be subjected to high differential thermal stresses in service. This treatment may advantageously consist in applying a reducing plasma with a starting gas containing hydrogen or water vapor.

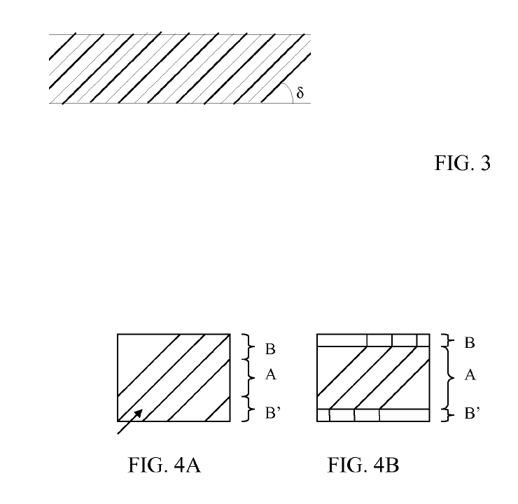

FIGS. 4A and 4B show various packing plates treated by the process of the invention.

In FIG. 4A, the corrugations run through the plate conventionally, making a constant angle with the edges of the plate. In this case, either the upper zone B or the lower zone B′, or both, are treated by a process according to the invention so as to reduce the wetting of their surfaces. The central zone A may also be treated using a process described above to increase the wetting thereof.

FIG. 4B shows a packing element with modified edges in which the angle of the corrugations approaches the vertical toward the lower and upper edges of the module. Thus, in zones B, B′, the angle of corrugation approaches 90° to the horizontal, whereas in zone A the angle is around 45° . In this case, either the upper zone B or the lower zone B′ or both is/are treated by a process according to the invention in order to reduce the wetting of their surfaces. The central zone A may also be treated by a process described above in order to increase the wetting thereof.

For the zones where the wetting is increased, it is also possible to increase the gas/liquid contact time in these zones, by other known means.

For the zones where the wetting is reduced, it is also possible to reduce the gas/liquid contact time in these zones, by other known means.

The relative heights of zones A, B, B′ may vary, but in general the zones B and B′ comprise between 2 and 20% of the height of the plate and the central zone A comprises between 60 and 96% of the height of the plate.

1-15. (canceled)

16. A process for treating a mass and/or heat transfer module, the device comprising a stack of cross-corrugated plates, comprising;
reducing the wetting of the surface of the plates in at least one zone of the module wherein the wetting is reduced only in at least one of the bottom and top interface zones of the module.

17. The process of claim 16, wherein the wetting is reduced:
i) by polishing the surface of the plates in at least one interface zone of the module or
ii) by chemically treating the surfaces of the plates in at least one interface zone (B, B′) of the module or
iii) by providing a physical and/or chemical treatment using a reactive gaseous atmosphere excited by an electrical discharge, in particular an atmospheric-pressure electrical discharge.

18. The process of claim 17, wherein the zone is immersed in a chemical bath.

19. The process of claim 17, wherein the zone is sprayed with a solution

20. The process of claim 17, wherein the electrical discharge being of the corona discharge, dielectric barrier discharge (DBD) or microwave discharge type.

21. The process of claim 16, wherein the wetting of at least one interface zone of the plate is reduced before folding.

22. The process of claim 16, wherein the wetting of at least one interface zone of the plate is reduced after folding.

23. The process of claim 16, wherein the wetting of the surface of the plates of the module is increased in the central zone of the module.

24. The process of claim 23, wherein the wetting is increased:
i) by immersing the plate in a liquid bath or by spraying it with a solution or
ii) by providing a physical and/or chemical treatment using a reactive gaseous atmosphere excited by an electrical discharge, in particular an atmospheric-pressure electrical discharge.

25. The process of claim 24, wherein the electrical discharge being of the corona discharge, dielectric barrier discharge (DBD) or microwave discharge type.

26. The process of claim 16, wherein the wetting of at least one zone of the module is reduced, with a gradient of properties of the plasma atmosphere through the module.

27. The process of claim 26, wherein the concentration of the injected gases and/or the electron density and electron temperature of the plasma is/are varied along the module.

28. The process of claim 16, wherein the changes in wetting properties are progressive between two contiguous zones.

29. The process of claim 16, wherein the wetting modification is combined with at least one modification in the geometry, density or material of the zone.

30. The process of claim 16, wherein the plates are made of aluminum or copper.

31. A packing module treated as claimed in claim 16.

32. A column, preferably an air gas distillation column, equipped with at least one packing module as claimed in claim 31.

33. The column of claim 32, wherein said column is an air gas distillation column.
